(19) United States
(12) Patent Application Publication
(10) Pub. No.: US 2022/0059557 A1
(43) Pub. Date: Feb. 24, 2022

(54) SEMICONDUCTOR STORAGE DEVICE

(71) Applicant: Kioxia Corporation, Tokyo (JP)

(72) Inventors: Suzuka KAJIWARA, Kuwana Mie (JP); Toshifumi KURODA, Yokkaichi Mie (JP)

(21) Appl. No.: 17/191,206

(22) Filed: Mar. 3, 2021

(30) Foreign Application Priority Data
Aug. 24, 2020 (JP) 2020-141080

(51) Int. Cl. H01L 27/11556; G11C 5/06; H01L 27/11582

(52) U.S. Cl. CPC H01L 27/11556; H01L 27/11582; G11C 5/06

(57) ABSTRACT

A semiconductor storage device includes a semiconductor substrate; a first structure body having a plurality of first conductive films and a plurality of first insulating films alternately stacked on the semiconductor substrate in a first direction vertical to the semiconductor substrate; a first semiconductor layer extending in the first direction; and a first memory cell disposed between the first semiconductor layer and the first structure body, in which the plurality of first conductive films include first portions, second portions, and third portions positioned between the first portion and the second portions in a second direction parallel to the semiconductor substrate and the first portions, second portions, and third portions disposed at different positions in a third direction parallel to the semiconductor substrate, and having curvatures from the first portions to the third portions and from the second portions to the third portions, and the first memory cell is disposed between the first semiconductor layer and the third portion.

### CROSS-REFERENCE TO RELATED APPLICATION

This application is based upon and claims the benefit of priority from Japanese Patent Application No. 2020-141080, filed on Aug. 24, 2020, the entire contents of which are incorporated herein by reference.

### FIELD

Embodiments described herein relate generally to a semiconductor storage device.

### BACKGROUND

A NAND-type flash memory is known as a nonvolatile semiconductor storage device. In order to increase the capacity of the NAND-type flash memory, a three-dimensional NAND-type flash memory having a configuration in which many memory cells are stacked is commercially available. In a three-dimensional NAND-type flash memory, electric field concentration occurs in end portions of the memory cells.

### DESCRIPTION OF THE DRAWINGS

FIGS. 1A to 1C are cross-sectional views illustrating a semiconductor storage device according to at least one embodiment;

FIGS. 2A to 2C are cross-sectional views illustrating a method of manufacturing the semiconductor storage device;

FIGS. 3A to 3C are cross-sectional views illustrating the method of manufacturing the semiconductor storage device;

FIGS. 4A to 4C are cross-sectional views illustrating the method of manufacturing the semiconductor storage device;

FIGS. 5A to 5C are cross-sectional views illustrating the method of manufacturing the semiconductor storage device;

FIGS. 6A to 6C are cross-sectional views illustrating the method of manufacturing the semiconductor storage device;

FIGS. 7A to 7C are cross-sectional views illustrating the method of manufacturing the semiconductor storage device;

FIGS. 8A to 8C are cross-sectional views illustrating the method of manufacturing the semiconductor storage device;

FIGS. 9A to 9C are cross-sectional views illustrating the method of manufacturing the semiconductor storage device;

FIGS. 10A to 10C are cross-sectional views illustrating the method of manufacturing the semiconductor storage device;

FIG. 11 is an enlarged cross-sectional view illustrating the semiconductor film 110 and the insulator 120 in a C region of FIG. 10A;

FIGS. 12A to 12C are cross-sectional views illustrating the method of manufacturing the semiconductor storage device;

FIGS. 13A to 13C are cross-sectional views illustrating the method of manufacturing the semiconductor storage device;

FIGS. 14A to 14C are cross-sectional views illustrating the method of manufacturing the semiconductor storage device; and

FIG. 15 is a cross-sectional view illustrating a semiconductor storage device according to a modified example.

### DETAILED DESCRIPTION

At least one embodiment provides a semiconductor storage device in which the electric field concentration in end portions of memory cells is reduced.

In general, according to at least one embodiment, a semiconductor storage device includes a semiconductor substrate; a first structure body having a plurality of first conductive films and a plurality of first insulating films alternately stacked on the semiconductor substrate in a first direction vertical to the semiconductor substrate; a first semiconductor layer extending in the first direction; and a first memory cell disposed between the first semiconductor layer and the first structure body, in which the plurality of first conductive films include first portions, second portions, and third portions that are positioned between the first portions and the second portions in a second direction parallel to the semiconductor substrate and the first portions, second portions, and third portions disposed at different positions in a third direction parallel to the semiconductor substrate, the plurality of first conductive films having curvatures from the first portions to the third portions and from the second portions to the third portions, and the first memory cell is disposed between the first semiconductor layer and the third portion.

Hereinafter, a semiconductor storage device related to at least one embodiment is specifically described with reference to the drawings. In the following description, components having substantially the same function and configuration are denoted by the same reference numerals, and repeated explanations are provided only when necessary. The embodiments provided below exemplify devices and methods for embodying the technical idea, and the technical idea of the embodiments do not limit the materials, shapes, structures, arrangements, and the like of components as follows. The technical idea of the embodiments may be modified in various ways within the scope of the claims.

In order to clarify the description, the drawings may schematically represent the width, thickness, shape, and the like of each part as compared with the actual aspect but are merely examples, and do not limit the interpretation of the present disclosure. In the present specification and each drawing, elements having the same functions as those described with respect to the drawings already described may be denoted by the same reference numerals and repeated description may be omitted.

A plurality of films formed by the same process have the same layer structure and are composed of the same material. In the present specification, even when a plurality of films have different functions or roles, the plurality of films thus formed by the same process are treated as films existing in the same layer.

[Configuration of Semiconductor Storage Device]

The configuration of the semiconductor storage device according to at least one embodiment is described below. In the drawings referred to below, an X direction corresponds to the stretching direction of a bit line, a Y direction corresponds to the stretching direction of a word line, and a Z direction corresponds to the surface of the semiconductor substrate on which a signal line (semiconductor film) is formed.

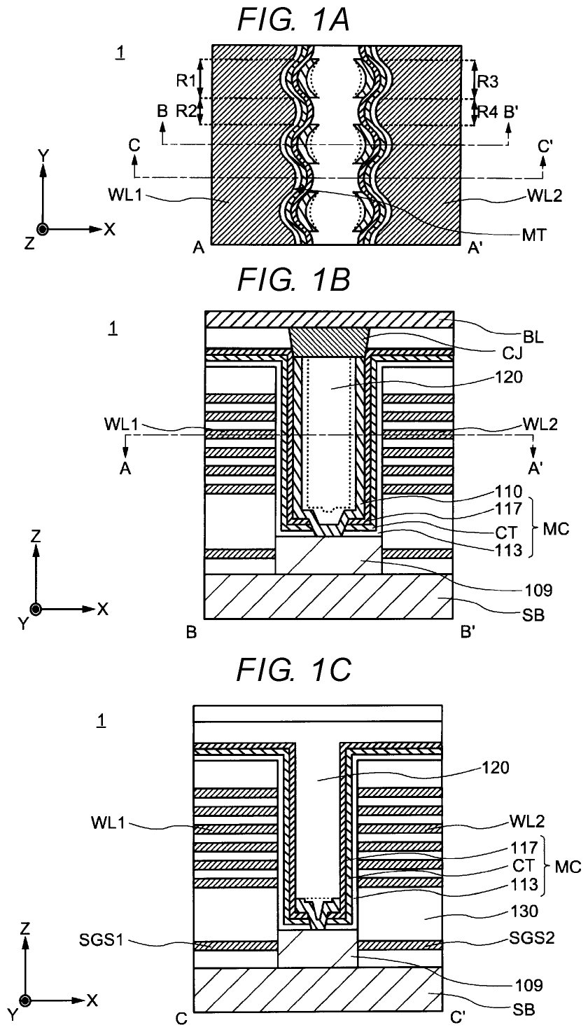

FIGS. 1A to 1C are cross-sectional views illustrating a semiconductor storage device according to at least one embodiment. FIG. 1A illustrates an example of a cross-sectional view taken along the line A-A′ illustrated in FIG. 1B in an XY plane. FIG. 1B illustrates an example of a cross-sectional view taken along the line B-B′ illustrated in FIG. 1A in an XZ plane. FIG. 1C illustrates an example of a cross-sectional view taken along the line C-C′ illustrated in FIG. 1A in the XZ plane.

A semiconductor storage device 1 includes a memory cell three-dimensionally arranged on the semiconductor substrate SB. Specifically, a memory string in which the semiconductor substrate SB and source-side select gate transistors, for example, 64 memory cells are connected in series in the vertical direction is configured. A dummy cell transistor may be provided at both ends of many memory cells connected in series and or between parts of portions between many memory cells.

As illustrated in FIGS. 1A to 1C, a stacked structure body in which a plurality of conductive films and a plurality of insulating films arranged in the XY plane parallel to the semiconductor substrate SB are alternately stacked in the Z direction is disposed on the semiconductor substrate SB. The plurality of conductive films correspond to source-side select gate lines SGS1 and SGS2 and word lines WL1 and WL2 connected to each transistor of the memory string. Here, when the source-side select gate lines SGS1 and SGS2 are not distinguished, the source-side select gate lines SGS1 and SGS2 are referred to as source-side select gate lines SGS. When the word lines WL1 and WL2 are not distinguished, the word lines WL1 and WL2 are referred to as word lines WL. In the drawing, one layer of the source-side select gate line SGS, six layers of the word lines WL, and insulating films 130 disposed therebetween are merely illustrated. However, the numbers of conductive films and insulating films are not limited particularly. A bit line BL is disposed on the stacked structure body. The semiconductor substrate SB is, for example, a silicon single crystal substrate. For example, a conductor such as tungsten is used for the plurality of conductive films. For example, an insulator such as silicon dioxide is used for the plurality of insulating films.

The word line WL1 and the word line WL2 are arranged in the same XY plane parallel to the semiconductor substrate SB. The word line WL1 and the word line WL2 extend in the Y direction, respectively. The word line WL1 and the word line WL2 are adjacent to each other in the X direction via a memory trench MT.

As illustrated in FIG. 1A, the word line WL1 includes first regions R1 and second regions R2 provided at a different position in the X direction with respect to the first regions R1. The second regions R2 protrude in the X direction with respect to the first regions R1. The first regions R1 and the second regions R2 are alternately arranged in the Y direction. The word line WL1 has curvatures from the recess portions of the first regions R1 toward the protrusions of the second regions R2 and curvatures from the protrusions of the second regions R2 toward the recess portions of the first regions R1. The recess portions of the first regions R1 and the protrusions of the second regions R2 that continue in the Y direction along the memory trench MT have curvatures that periodically fluctuate. The recess portions of the first regions R1 and the protrusions of the second regions R2 that continue in the Y direction form a wavy line with gentle undulations (concavo-convex structure) in the X direction, in the Y direction. The word line WL2 includes third regions R3 and fourth regions R4 provided at different positions in the X direction with respect to the third regions R3. The fourth regions R4 protrude in the X direction with respect to the third regions R3. The third regions R3 and the fourth regions R4 are alternately arranged in the Y direction. The word line WL2 has curvatures from the recess portions of the third regions R3 and the protrusions of the fourth regions R4, and curvatures from the protrusions of the fourth regions R4 and the recess portions of the third regions R3. The recess portions of the third regions R3 and the protrusions of the fourth regions R4 that continue in the Y direction along the memory trench MT have curvatures that periodically fluctuate. The recess portions of the third regions R3 and the protrusion of the fourth regions R4 that continue in the Y direction form a wavy line with gentle undulations (concavo-convex structure) in the X direction, in the Y direction.

As illustrated in FIG. 1A, the first regions R1 of the word line WL1 and the third regions R3 and the word line WL2 are arranged at the same position in the Y direction and face with each other via the memory trench MT. The second regions R2 of the word line WL1 and the fourth regions R4 of the word line WL2 are arranged at the same position in the Y direction and face each other via the memory trench MT. Therefore, the second regions R2 of the word line WL1 and the fourth regions R4 of the word line WL2 are closer to each other than the first regions R1 of the word line WL1 and the third regions R3 of the word line WL2. In other words, the width of the memory trench MT between the first regions R1 of the word line WL1 and the third regions R3 of the word line WL2 illustrated in FIG. 1B is wider than the width of the memory trench MT between the second regions R2 of the word line WL1 and the fourth regions R4 of the word line WL2 illustrated in FIG. 1C in the X direction.

The plurality of conductive films and the plurality of insulating films alternately stacked in the Z direction respectively include the memory trench MT arranged at the same position in the XY plane. Therefore, the plurality of conductive films and the plurality of insulating films alternately stacked in the Z direction include the first regions R1, the second regions R2, the third regions R3, and the fourth regions R4 at the same position in the XY plane, respectively. The first regions R1, the second regions R2, the third regions R3, and the fourth regions R4 of the conductive films and the plurality of insulating films alternately stacked in the Z direction continue in the Z direction, respectively. That is, the recess portions of the first regions R1 and the protrusion of the second regions R2 that continue in the YZ plane along the memory trench MT form a wavy surface with gentle undulations (a surface having concavo-convex structure) in the X direction. The recess portions of the third regions R3 and the protrusion of the fourth regions R4 that continue in the YZ plane along the memory trench MT form a wavy surface with gentle undulations in the X direction (a surface having concavo-convex structure).

An insulating layer 109, a memory cell MC, and semiconductor film 110 is disposed in the memory trench MT penetrating the stacked structure body.

The bottom portion of the memory trench MT that penetrates the stacked structure body reaches the semiconductor substrate SB. The insulating layer 109 is disposed in contact with the semiconductor substrate SB in the bottom portion of the memory trench MT. The insulating layer 109 is formed, for example, by epitaxially growing a silicon single crystal on the semiconductor substrate SB using a silicon single crystal. The insulating layer 109 may be partially embedded in the semiconductor substrate SB. The insulating layer 109 is connected to the source-side select gate line SGS via an insulator (not illustrated) and becomes a portion of the source-side select gate transistor. That is, the insulating layer 109 is arranged from the semiconductor substrate SB to a portion between the source-side select gate line SGS and the word line WL of the lowermost layer in the Z direction.

A block layer (second insulating layer) 113, a charge trap layer (first charge storage layer) CT, and a tunnel layer (first insulating layer) 117 are arranged from the inner surface of the memory trench MT (the outer surface of the plurality of conductive films and the plurality of insulating films) and the upper portion of the insulating layer 109 toward the center of the memory trench MT inside the memory trench MT. The block layer 113 is disposed in contact with the inner surface of the memory trench MT (the outer surface of the plurality of conductive films and the plurality of insulating films) and the insulating layer 109. The charge trap layer CT is disposed in contact with the block layer 113. The tunnel layer 117 is disposed in contact with the charge trap layer CT. The block layer 113 may be a silicon dioxide film, the charge trap layer CT may be a silicon nitride film, and the tunnel layer 117 may be a silicon oxynitride film. Here, when the block layer 113, the charge trap layer CT, and the tunnel layer 117 are not distinguished respectively, the block layer 113, the charge trap layer CT, and the tunnel layer 117 are referred to as the memory cell MC.

The block layer 113 is disposed in contact with the first regions R1, the second regions R2, the third regions R3, the fourth regions R4 of the plurality of conductive films and the plurality of insulating films. The memory cell MC disposed on the inner surface of the memory trench MT reflects the concavo-convex structure formed by the recess portions of the first regions R1 and the protrusions of the second regions R2 of the plurality of conductive films and the plurality of insulating films and the concavo-convex structure formed by the recess portions of the third regions R3 and the protrusions of the fourth regions R4 of the plurality of conductive films and the plurality of insulating films. The memory cell MC continues in the Y direction and has a curvature that periodically fluctuates. That is, the memory cell MC is stacked as a wavy surface with gentle undulations (a surface having concavo-convex structure) in the X direction on the outer surface of the plurality of conductive films and the plurality of insulating films. The memory cell MC is also stacked on the upper surface of the stacked structure body (the plurality of conductive films and the plurality of insulating films). The memory cell MC has an opening on the insulating layer 109.

A semiconductor pillar that is in contact with the tunnel layer 117 and the insulating layer 109 of the memory cell MC are further arranged opposite to the block layer 113 side in contact with the outer surface of the plurality of conductive films and the plurality of insulating films of the memory cell MC. The semiconductor pillar includes the semiconductor film 110 and an insulator 120 from the tunnel layer 117 of the memory cell MC toward the center of the memory trench MT. The semiconductor film 110 may be an amorphous or polycrystalline silicon film. The insulator 120 may be a silicon dioxide film.

The semiconductor film 110 is stacked on the first regions R1 and the third regions R3 of the plurality of conductive films and the plurality of insulating films via the memory cell MC. The semiconductor film 110 is discontinuous in a region corresponding to the second regions R2 and the fourth regions R4 of the plurality of conductive films and the plurality of insulating films. That is, the semiconductor film 110 is respectively disposed on the recess portions of the memory cell MC stacked on the outer surface of the plurality of conductive films and the plurality of insulating films and are not disposed on the protrusions. The semiconductor film 110 reflects concave structures of the first regions R1 of the plurality of conductive films and the plurality of insulating films or the concave structures of the third regions R3 of the plurality of conductive films and the plurality of insulating films. The semiconductor films 110 is periodically arranged as an arc surface having the plurality of discontinuous curvatures (a surface having a concave structure) in the Y direction on the outer surface of the plurality of conductive films and the plurality of insulating films. The semiconductor film 110 extends in the Z direction and is connected to the insulating layer 109 via the opening of the memory cell MC at one end on the semiconductor substrate SB side. The semiconductor film 110 is connected to the bit line BL via a connection plug CJ at the other end opposite to the semiconductor substrate SB. According to at least one embodiment, the bit line BL extends in the X direction to be orthogonal to the Y direction in which the memory trench MT extends. However, the direction in which the bit line BL is centrifuged is not particularly limited.

The insulator 120 is disposed in contact with the tunnel layer 117 and the semiconductor film 110 of the memory cell MC. The insulator 120 fills the inside of the memory trench MT.

The semiconductor film 110 is connected to the first regions R1 of the word line WL1 or the third regions R3 of the word line WL2 via the memory cell MC and functions as a part of the memory cell that traps electric charges in the charge trap layer CT. The semiconductor storage device 1 according to at least one embodiment has an arc shape in which the semiconductor film 110 has a convex curvature with respect to the word line WL in the central portion via the memory cell MC. Since the semiconductor film 110 has such a structure, it is possible to reduce the electric field concentration in the end portion of the semiconductor film 110, improve injection efficiency of the electric charges to the charge trap layer CT via the tunnel layer 117 (writing window), and prevent the leaving of electric charges injected to the charge trap layer CT into the block layer 113 (write saturation).

[Method of Manufacturing Semiconductor Storage Device]

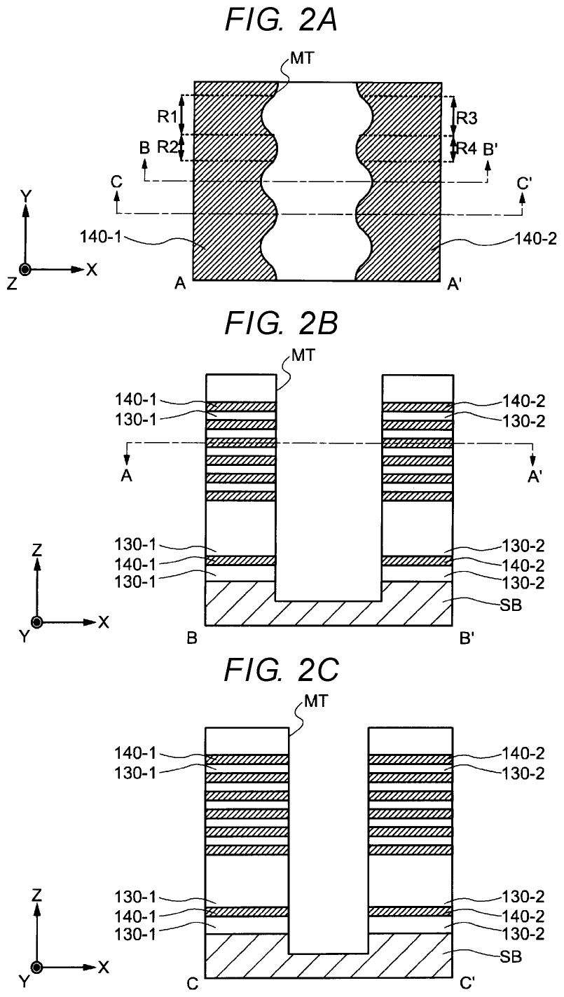

A method of manufacturing the semiconductor storage device according to at least one embodiment is described. FIGS. 2A to 2C are cross-sectional views illustrating steps for forming the memory trench MT in stacked structure body in the method of manufacturing the semiconductor storage device according to at least one embodiment. FIG. 2A illustrates an example of the cross-sectional view taken along the line A-A′ illustrated in FIG. 2B in the XY plane. FIG. 2B illustrates an example of the cross-sectional view taken along the line B-B′ illustrated in FIG. 2A in the XZ plane. FIG. 2C illustrates an example of the cross-sectional view taken along the line C-C′ illustrated in FIG. 2A in the XZ plane.

As illustrated in FIGS. 2A to 2C, a stacked structure body in which the plurality of insulating films 130 and a plurality of dummy films 140 are alternately stacked on the semiconductor substrate SB is formed. The plurality of insulating films 130 may, for example, a silicon dioxide film. The plurality of dummy films 140 may be silicon nitride films. The plurality of insulating films 130 and the plurality of dummy films 140 are formed, for example, by a CVD apparatus.

Subsequently, the memory trench MT is formed, for example, by selectively etching the stacked structure body by using a mask. The memory trench MT is formed by removing a part of the plurality of insulating films 130 and the plurality of dummy films 140 in the Z direction, for example, by using anisotropic reactive ion etching. The memory trench MT exposes a part of the semiconductor substrate SB. Here, the bottom surface of the memory trench MT may be lower than the upper surface of the semiconductor substrate SB. That is, the semiconductor substrate SB may be partially etched by the etching of the stacked structure body.

The memory trench MT is formed to extend in the Y direction and divide the stacked structure body in the X direction. The plurality of insulating films 130 are divided into a plurality of insulating films 130-1 and a plurality of insulating films 130-2, respectively. The plurality of dummy films 140 are divided into a plurality of dummy films 140-1 and a plurality of dummy films 140-2. Here, when the plurality of insulating films 130-1 and the plurality of insulating films 130-2 are not distinguished, the plurality of insulating films 130-1 and the plurality of insulating films 130-2 are referred to as the plurality of insulating films 130. When the plurality of dummy films 140-1 and the plurality of dummy films 140-2 are not distinguished, the plurality of dummy films 140-1 and the plurality of dummy films 140-2 are referred to as the plurality of dummy films 140.

The width of the memory trench MT in the X direction is formed to have the curvature that periodically fluctuates. Therefore, the plurality of insulating films 130-1 and the plurality of dummy films 140-1 divided by the memory trench MT include the first regions R1 and the second regions R2 that protrude in the X direction with respect to the first regions R1. The first regions R1 and the second regions R2 are alternately arranged in the Y direction. The plurality of insulating films 130-1 and the plurality of dummy films 140-1 have curvatures from the recess portions of the first regions R1 toward the protrusions of the second regions R2 and curvatures from the protrusions of the second regions R2 toward the recess portions of the first regions R1. The recess portions of the first regions R1 and the protrusions of the second regions R2 that continue in the Y direction have curvatures that periodically fluctuate. The first regions R1 and the second regions R2 continue in the Z direction, respectively. That is, the recess portions of the first regions R1 and the protrusions of the second regions R2 continue in the YZ plane. A wavy surface with gentle undulations (a surface having concavo-convex structure) in the X direction is formed in the YZ plane. The plurality of insulating films 130-2 and the plurality of dummy films 140-2 divided by the memory trench MT include the third regions R3 and the fourth regions R4 that protrude in the X direction with respect to the third regions R3, respectively. The third regions R3 and the fourth regions R4 are alternately arranged in the Y direction. The plurality of insulating films 130-2 and the plurality of dummy films 140-2 have curvatures from the recess portions of the third regions R3 and the protrusions of the fourth regions R4 and curvatures from the protrusions of the fourth regions R4 toward the recess portions of the third regions R3. The recess portions of the third regions R3 and the protrusions of the fourth regions R4 that continue in the Y direction have curvatures that periodically fluctuate. The third regions R3 and the fourth regions R4 respectively continue in the Z direction. That is, the recess portions of the third regions R3 and the protrusions of the fourth regions R4 that continue in the YZ plane form a wavy surface with gentle undulations (a surface having concavo-convex structure) in the X direction, in the YZ plane.

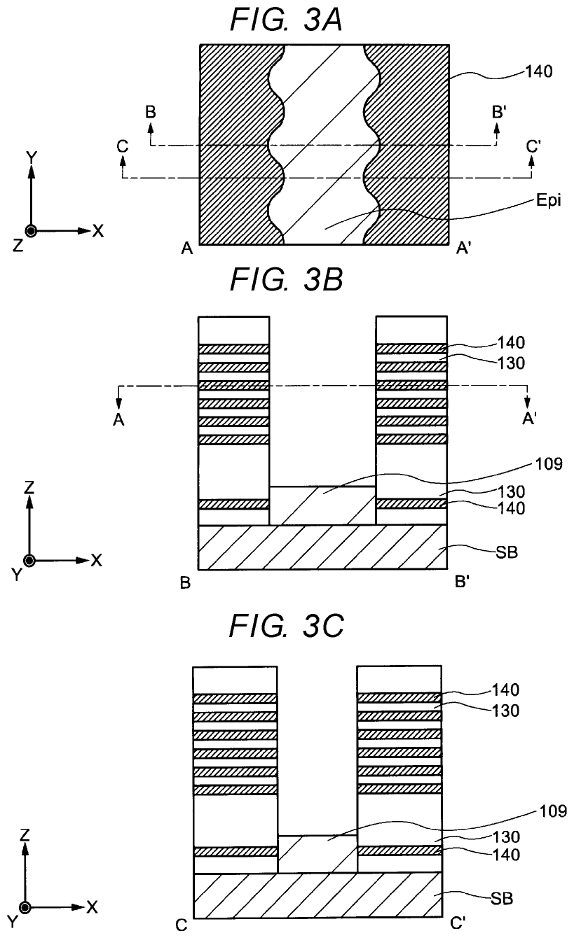

FIGS. 3A to 3C are cross-sectional views illustrating steps for forming the insulating layer 109 in the bottom portion of the memory trench MT in the method of manufacturing the semiconductor storage device according to at least one embodiment. FIG. 3A illustrates an example of a cross-sectional view taken along the line A-A′ illustrated in FIG. 3B in the XY plane. FIG. 3B illustrates an example of a cross-sectional view taken along the line B-B′ illustrated in FIG. 3A in the XZ plane. FIG. 3C illustrates an example of a cross-sectional view taken along the line C-C′ illustrated in FIG. 3A in the XZ plane.

As illustrated in FIGS. 3A to 3C, a silicon single crystal is epitaxially grown by using the semiconductor substrate SB in the bottom portion of the memory trench MT as a seed crystal. The silicon single crystal may be epitaxially grown, for example, by using a CVD apparatus. As the Si raw material gas used for epitaxial growth, for example, monosilane (SiH₄), dichlorosilane (SiH₂Cl₂), trichlorosilane (SiHCl₃) and the like may be used. The insulating layer 109 according to at least one embodiment is formed from the bottom portion of the memory trench MT (the semiconductor substrate SB) to the dummy films 140 of the lowermost layer.

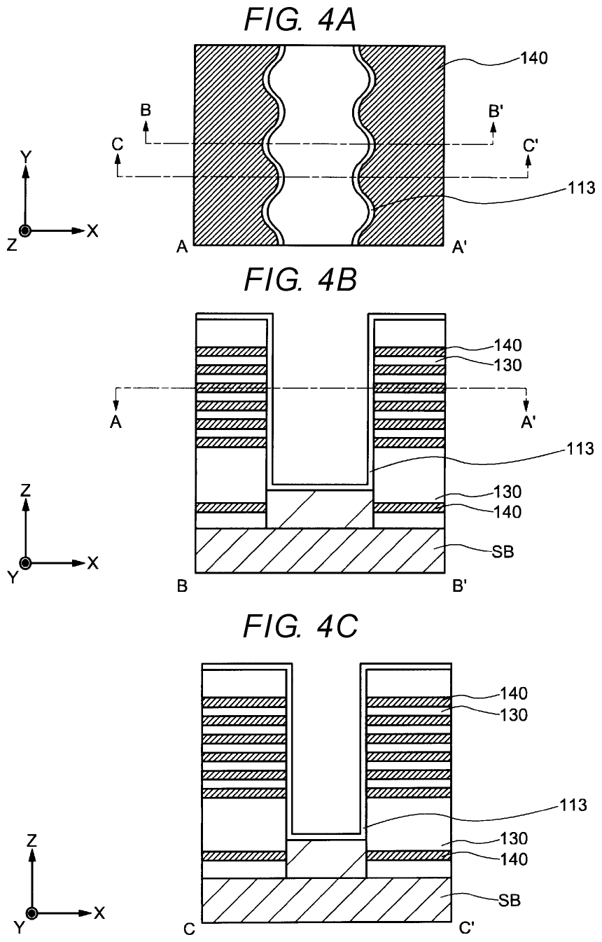

FIGS. 4A to 4C are cross-sectional views illustrating steps for forming the block layer 113 in the method of manufacturing the semiconductor storage device according to at least one embodiment. FIG. 4A is an example of the cross-sectional view taken along the line A-A′ illustrated in FIG. 4B in the XY plane. FIG. 4B is an example of the cross-sectional view taken along the line B-B′ illustrated in FIG. 4A in the XZ plane. FIG. 4C is an example of the cross-sectional view taken along the line C-C′ illustrated in FIG. 4A in the XZ plane.

As illustrated in FIG. 4A to FIG. 4C, the block layer 113 is formed substantially the entire surface of the stacked structure body. That is, the block layer 113 is formed to be in contact with the first regions R1 and the second regions R2 of the plurality of insulating films 130-1 and the plurality of dummy films 140-1 and the third regions R3 and the fourth regions R4 of the plurality of insulating films 130-2 and the plurality of dummy films 140-2 that cover the inner surface of the memory trench MT. Therefore, the block layer 113 is formed as a wavy surface with gentle undulations (a surface having concavo-convex structure) in the X direction on the inner surface of the memory trench MT. The block layer 113 is formed to cover the upper surface of the insulating layer 109 in the bottom portion of the memory trench MT and the upper surface of the stacked structure body (the insulating film 130 of the uppermost layer). As the block layer 113, a silicon dioxide film may be formed by, for example, oxidizing a silicon nitride film formed by using CVD.

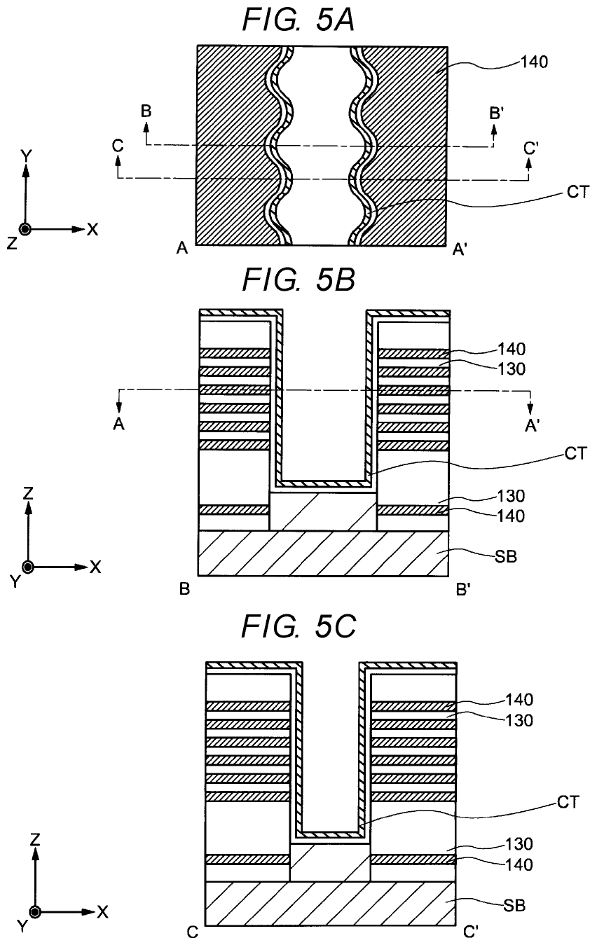

FIGS. 5A to 5C are cross-sectional views illustrating steps for forming the charge trap layer CT in the method of manufacturing the semiconductor storage device according to at least one embodiment. FIG. 5A illustrates an example of a cross-sectional view taken long the line A-A′ illustrated in FIG. 5B. FIG. 5B illustrates an example of a cross-sectional view taken long the line B-B′ illustrated in FIG. 5A in the XZ plane. FIG. 5C illustrates an example of a cross-sectional view taken long the line C-C′ illustrated in FIG. 5A in the XZ plane.

As illustrated in FIGS. 5A to 5C, the charge trap layer CT is formed on substantially the entire surface of the stacked structure body. That is, the charge trap layer CT is formed to be in contact with the block layer 113 to cover the inner surface of the memory trench MT. Therefore, the charge trap layer CT is formed as a wavy surface with gentle undulations (a surface having concavo-convex structure) in the X direction on the inner surface of the memory trench MT. The charge trap layer CT is formed to cover the block layer 113 of the bottom portion of the memory trench MT and the stacked structure body (on the block layer 113). The charge trap layer CT may be a silicon nitride film formed by using CVD, for example.

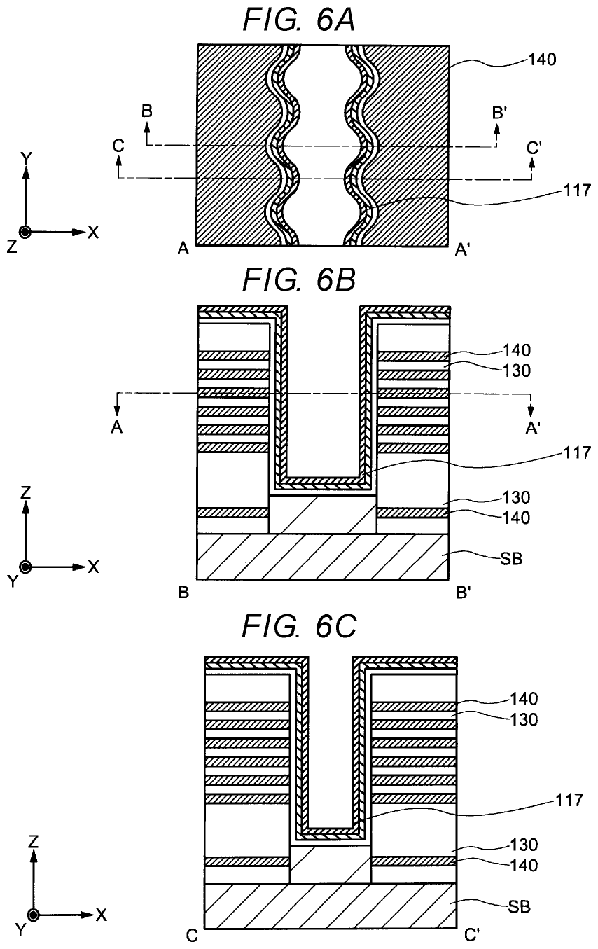

FIGS. 6A to 6C are cross-sectional views illustrating steps for forming the tunnel layer 117 in the method of manufacturing the semiconductor storage device according to at least one embodiment. FIG. 6A illustrates an example of a cross-sectional view taken long the line A-A′ illustrated in FIG. 6B in the XY plane. FIG. 6B illustrates an example of a cross-sectional view taken long the line B-B′ illustrated in FIG. 6A in the XZ plane. FIG. 6C illustrates an example of a cross-sectional view taken long the line C-C′ illustrated in FIG. 6A in the XZ plane.

As illustrated in FIGS. 6A to 6C, the tunnel layer 117 is formed on substantially the entire surface of the stacked structure body. That is, the tunnel layer 117 is formed to be in contact with the charge trap layer CT to cover the inner surface of the memory trench MT. Therefore, the tunnel layer 117 is formed as a wavy surface with gentle undulations (a surface having concavo-convex structure) in the X direction on the inner surface of the memory trench MT. The tunnel layer 117 is formed to cover the charge trap layer CT in the bottom portion of the memory trench MT and the stacked structure body (on the charge trap layer CT). The tunnel layer 117 may be a silicon oxynitride film formed, for example, by CVD.

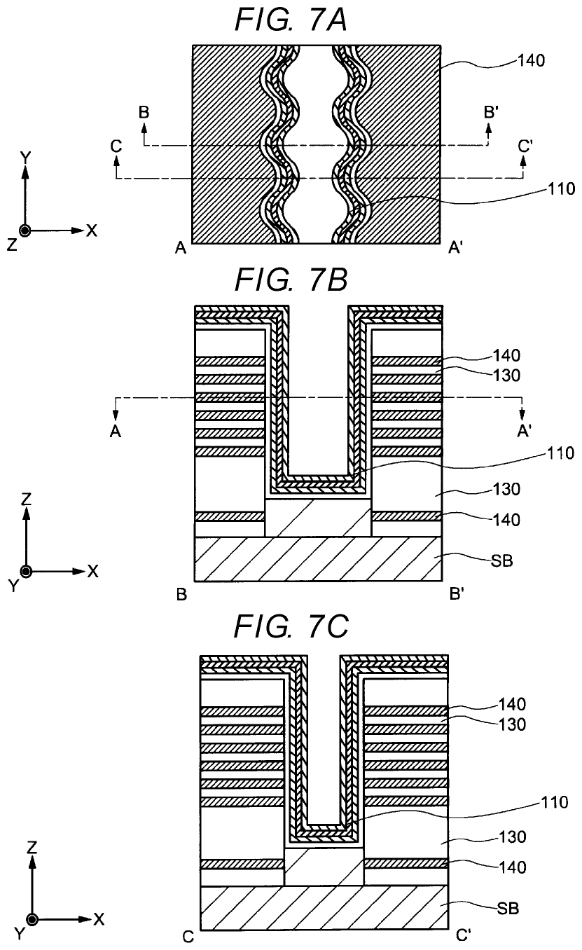

FIGS. 7A to 7C are cross-sectional views illustrating steps for forming the semiconductor film 110 in the method of manufacturing the semiconductor storage device according to at least one embodiment. FIG. 7A illustrates an example of a cross-sectional view taken long the line A-A′ illustrated in FIG. 7B in the XY plane. FIG. 7B illustrates an example of a cross-sectional view taken long the line B-B′illustrated in FIG. 7A in the XZ plane. FIG. 7C illustrates an example of a cross-sectional view taken long the line C-C′ illustrated in FIG. 7A in the XZ plane.

As illustrated in FIGS. 7A to 7C, the semiconductor film 110 is formed on substantially the entire surface of the stacked structure body. That is, the semiconductor film 110 is formed to be in contact with the tunnel layer 117 to cover the inner surface of the memory trench MT. Therefore, the semiconductor film 110 is formed as a wavy surface with gentle undulations (a surface having concavo-convex structure) in the X direction on the inner surface of the memory trench MT. The semiconductor film 110 is formed to cover the tunnel layer 117 in the bottom portion of the memory trench MT and the stacked structure body (on the tunnel layer 117). The semiconductor film 110 may be an amorphous or polycrystalline silicon film formed, for example, by using CVD.

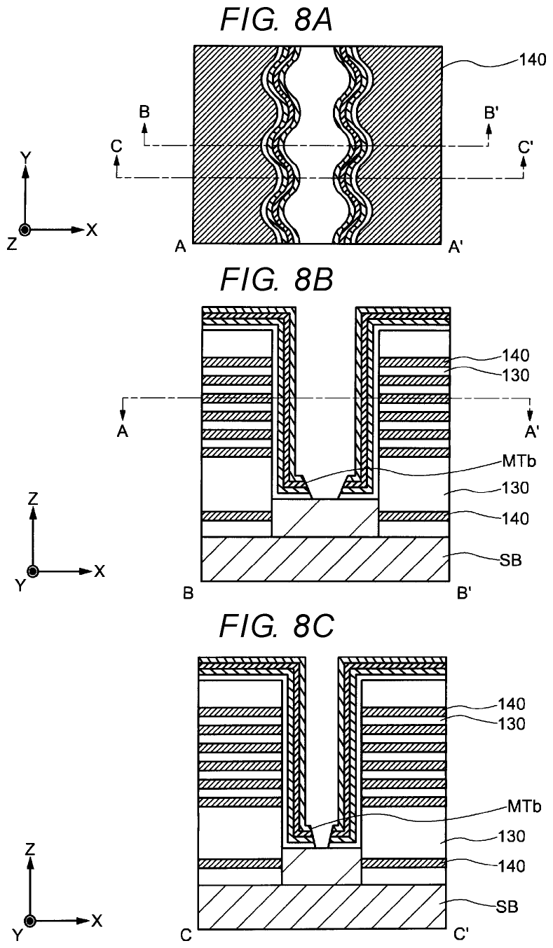

FIGS. 8A to 8C are cross-sectional views illustrating steps for forming an opening MTb in the method of manufacturing the semiconductor storage device according to at least one embodiment. FIG. 8A illustrates an example of a cross-sectional view taken long the line A-A′ illustrated in FIG. 8B in the XY plane. FIG. 8B illustrates an example of a cross-sectional view taken long the line B-B′ illustrated in FIG. 8A in the XZ plane. FIG. 8C illustrates an example of a cross-sectional view taken long the line C-C′ illustrated in FIG. 8A in the XZ plane.

As illustrated in FIGS. 8A to 8C, the opening MTb is formed by selectively etching the block layer 113, the charge trap layer CT, the tunnel layer 117, and the semiconductor film 110 stacked in the bottom portion of the memory trench MT. The opening MTb is formed by respectively removing a part of the block layer 113, the charge trap layer CT, the tunnel layer 117, and the semiconductor film 110 in the Z direction, for example, by using anisotropic reactive ion etching. The opening MTb exposes a part of the insulating layer 109.

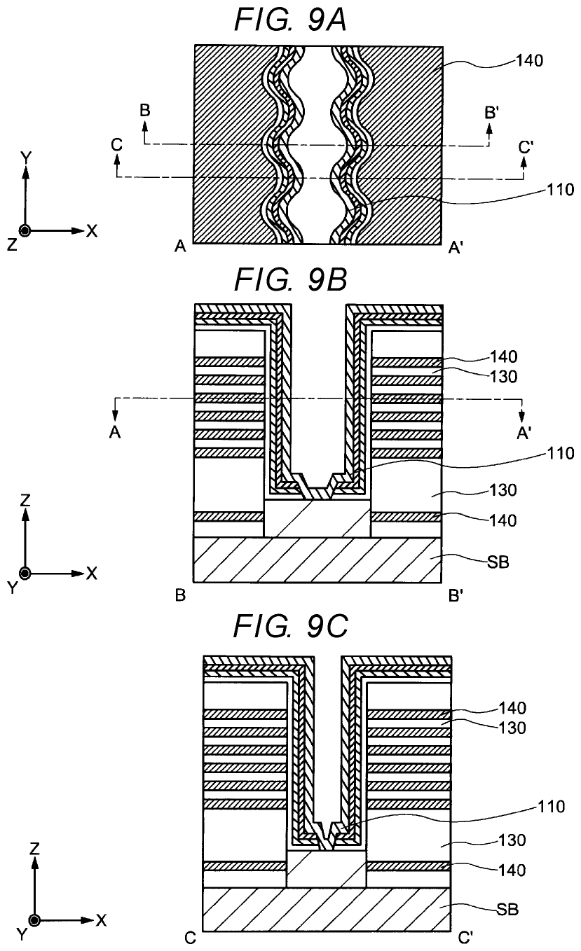

FIGS. 9A to 9C are cross-sectional views illustrating steps for further forming the semiconductor film 110 in the method of manufacturing the semiconductor storage device according to at least one embodiment. FIG. 9A illustrates an example of a cross-sectional view taken long the line A-A′ illustrated in FIG. 9B in the XY plane. FIG. 9B illustrates an example of a cross-sectional view taken long the line B-B′ illustrated in FIG. 9A in the XZ plane. FIG. 9C illustrates an example of a cross-sectional view taken long the line C-C′ illustrated in FIG. 9A in the XZ plane.

As illustrated in FIGS. 9A to 9C, the semiconductor film 110 is formed on substantially the entire surface of the stacked structure body. That is, the semiconductor film 110 is formed to be in contact with the semiconductor film 110 formed as illustrated in FIGS. 7A to 7C to cover the inner surface of the memory trench MT. The semiconductor film 110 is formed as a wavy surface with gentle undulations (a surface having concavo-convex structure) in the X direction on the inner surface of the memory trench MT. The semiconductor film 110 is formed to cover the semiconductor film 110 formed as illustrated in FIGS. 7A to 7C in the bottom portion of the memory trench MT and the opening MTb. The semiconductor film 110 is formed to be in contact with the block layer 113, the charge trap layer CT, and the tunnel layer 117 on the inner surface of the opening MTb. The semiconductor film 110 is formed to be in contact with the insulating layer 109 in the bottom portion of the opening MTb. The semiconductor film 110 is formed to cover the stacked structure body (on the semiconductor film 110 formed as illustrated in FIGS. 7A to 7C). The semiconductor film 110 may be an amorphous or polycrystalline silicon film formed, for example, by using CVD.

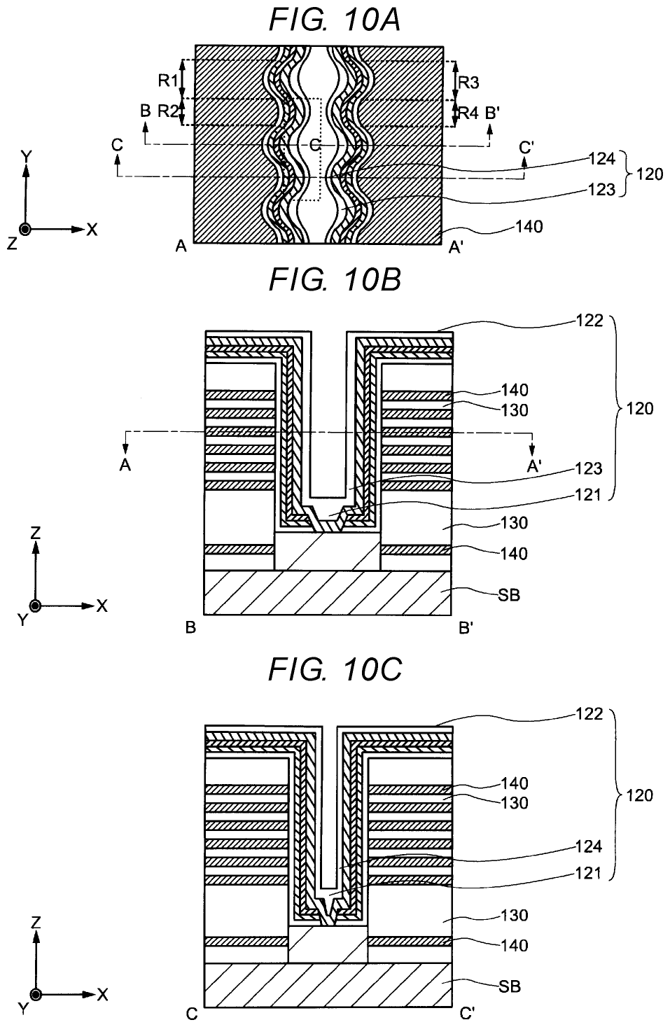

FIGS. 10A to 10C are cross-sectional views illustrating steps for forming the insulator 120 in the method of manufacturing the semiconductor storage device according to at least one embodiment. FIG. 10A illustrates an example of a cross-sectional view taken long the line A-A′ illustrated in FIG. 10B in the XY plane. FIG. 10B illustrates an example of a cross-sectional view taken long the line B-B′ illustrated in FIG. 10A in the XZ plane. FIG. 10C illustrates an example of a cross-sectional view taken long the line C-C′ illustrated in FIG. 10A in the XZ plane.

As illustrated in FIGS. 10A to 10C, the insulator 120 is formed on substantially the entire surface of the stacked structure body. That is, the insulator 120 is formed to be in contact with the semiconductor film 110 to cover the inner surface of the memory trench MT. The insulator 120 is formed as a wavy surface with gentle undulations (a surface having concavo-convex structure) in the X direction on the inner surface of the memory trench MT. The insulator 120 is formed to cover the semiconductor film 110 in the bottom portion of the memory trench MT. The insulator 120 is formed to cover the stacked structure body (on the semiconductor film 110). The insulator 120 may be a silicon nitride film formed, for example, by using CVD. However, the present embodiment is not limited thereto, and the insulator 120 may be a material having a selective ratio with that of the semiconductor film 110 in etching of the semiconductor film 110 described below.

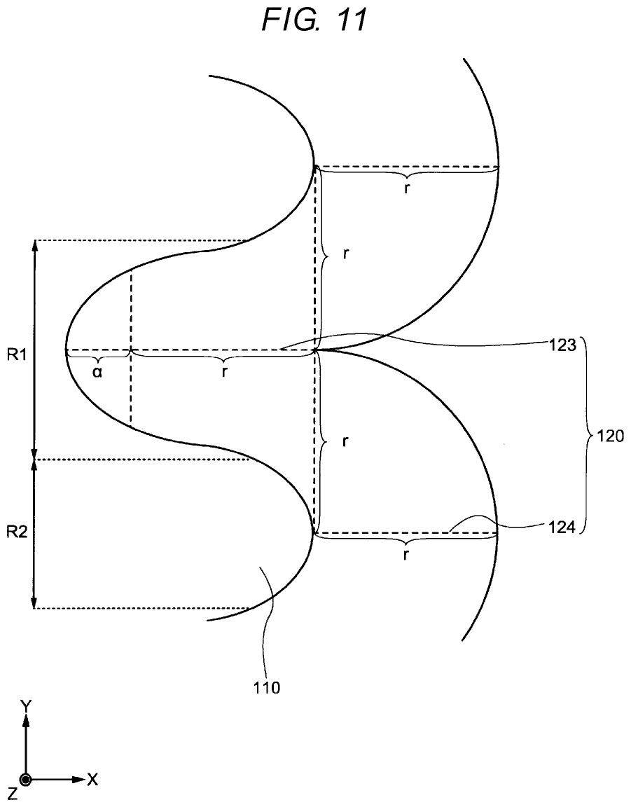

FIG. 11 is an enlarged cross-sectional view illustrating the semiconductor film 110 and the insulator 120 in a C region of FIG. 10A. As illustrated in FIG. 11, the semiconductor film 110 includes the concave structures in the first regions R1 on the plurality of insulating films 130-1 and the plurality of dummy films 140-1 via the memory cell MC, and the convex structures in the second regions R2 of the plurality of insulating films 130-1 and the plurality of dummy films 140-1 via the memory cell MC. If a minimum repeating unit (R1+R2) of the concavo-convex structure of the first region R1 and the second region R2 in the Y direction is set as 2r, the maximum width of the concavo-convex structure from the concave structure of the first region R1 to the convex structure of the second region R2 in the X direction is preferably r+α.

The semiconductor film 110 has the concavo-convex structure with undulations in the X direction, and thus the insulator 120 is formed in different film thicknesses in the first regions R1 and the second regions R2. If the film thickness of an insulator 124 in the convex structure of the semiconductor film 110 is formed to be r, the film thickness of an insulator 123 on the concave structure of the semiconductor film 110 is formed to be r+α. That is, the film of the insulator 123 in the first regions R1 of the plurality of insulating films 130-1 and the plurality of dummy films 140-1 and the third regions R3 of the plurality of insulating films 130-2 and the plurality of dummy films 140-2 is formed to be thick (r+α) via the memory cell MC and the semiconductor film 110. The film thickness of the insulator 124 in the second regions R2 of the plurality of insulating films 130-1 and the plurality of dummy films 140-1 and the fourth regions R4 of the plurality of insulating films 130-2 and the plurality of dummy films 140-2 is formed to be thin (r) via the memory cell MC and the semiconductor film 110. The film thickness of an insulator 121 on the semiconductor film 110 in the bottom portion of the memory trench MT is formed to be thick. The film thickness of an insulator 122 on the stacked structure body (on the semiconductor film 110) is formed to be thin. Here, when the insulators 121, 122, 123, and 124 are not distinguished, the insulators 121, 122, 123, and 124 are referred to as the insulator 120.

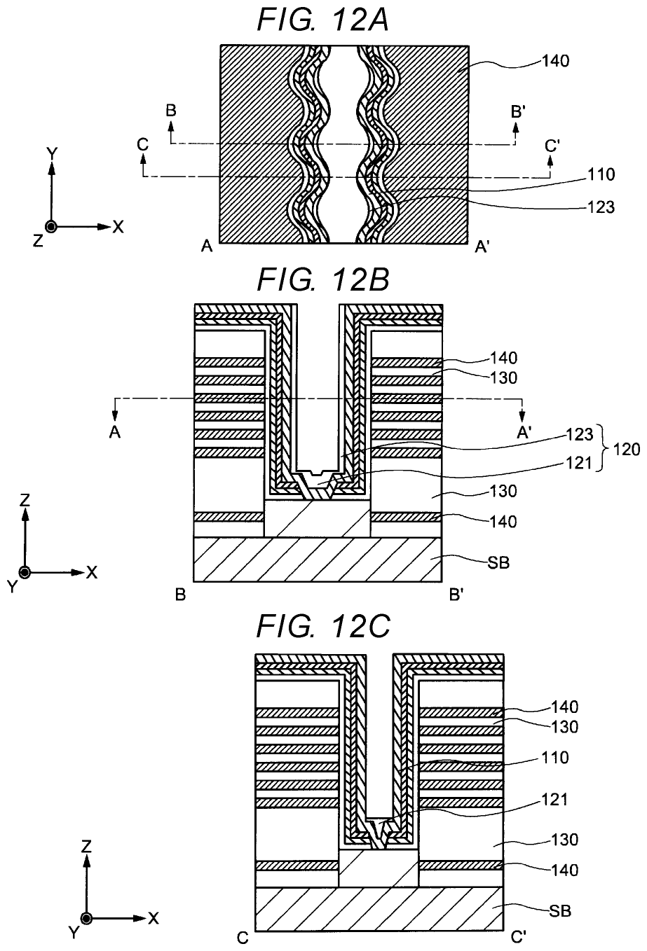

FIGS. 12A to 12C are cross-sectional views illustrating steps for removing a part of the insulator 120 in the method of manufacturing the semiconductor storage device according to at least one embodiment. FIG. 12A illustrates an example of a cross-sectional view taken long the line A-A′ illustrated in FIG. 12B in the XY plane. FIG. 12B illustrates an example of a cross-sectional view taken long the line B-B′ illustrated in FIG. 12A in the XZ plane. FIG. 12C illustrates an example of a cross-sectional view taken long the line C-C′ in FIG. 12A in the XZ plane.

As illustrated in FIGS. 12A to 12C, a part of the insulator 120 is removed by etching the insulator 120 formed in different thicknesses. The insulator 120 can remove only a region having a thin film thickness formed by, for example, wet etching with phosphoric acid. Only the insulator 124 in the convex structure of the semiconductor film 110 (the second regions R2 and the fourth regions R4) and the insulator 122 in the stacked structure body (on the semiconductor film 110) are removed so that the insulator 123 in the concave structure of the semiconductor film 110 formed to have the thick film thickness (the first regions R1 and the third regions R3) and the insulator 121 of the semiconductor film 110 in the bottom portion of the memory trench MT can remain (formed). That is, the insulator 120 exposes the semiconductor film 110 on the convex structure (the second regions R2 and the fourth regions R4) and the stacked structure body.

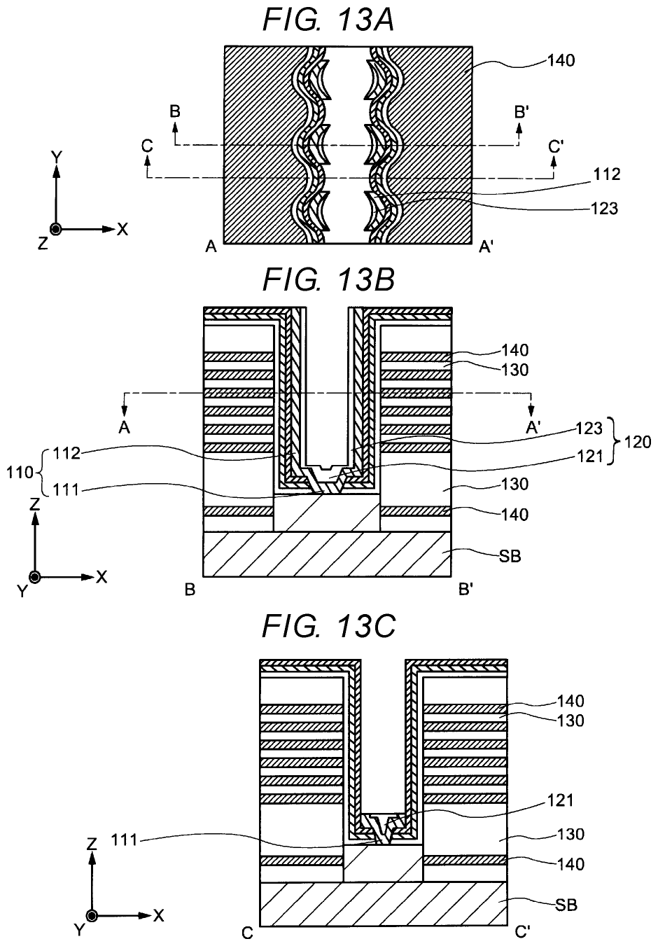

FIGS. 13A to 13C are cross-sectional views illustrating steps for selectively removing a part of the semiconductor film 110 in the method of manufacturing the semiconductor storage device according to at least one embodiment. FIG. 13A illustrates an example of a cross-sectional view taken long the line A-A′ illustrated in FIG. 13B in the XY plane. FIG. 13B illustrates an example of a cross-sectional view taken long the line B-B′ illustrated in FIG. 13A in the XZ plane. FIG. 13C illustrates an example of a cross-sectional view taken long the line C-C′ illustrated in FIG. 13A in the XZ plane.

As illustrated in FIG. 13A to FIG. 13C, a part of the semiconductor film 110 is removed by etching the insulator 120 as a mask. The semiconductor film 110 can selectively remove only regions exposed from the insulator 120 by, for example, wet etching using choline (trimethyl-2-hydroxyethylammonium hydroxide aqueous solution). A semiconductor film 112 on the concave structure (the first regions R1 and the third regions R3) covered with the insulator 123 and the insulator 121 and a semiconductor film 111 in the bottom portion of the memory trench MT can remain. That is, the semiconductor film 110 becomes discontinuous on the convex structure (the second regions R2 and the fourth regions R4) and the stacked structure body and exposes the tunnel layer 117 of the memory cell MC.

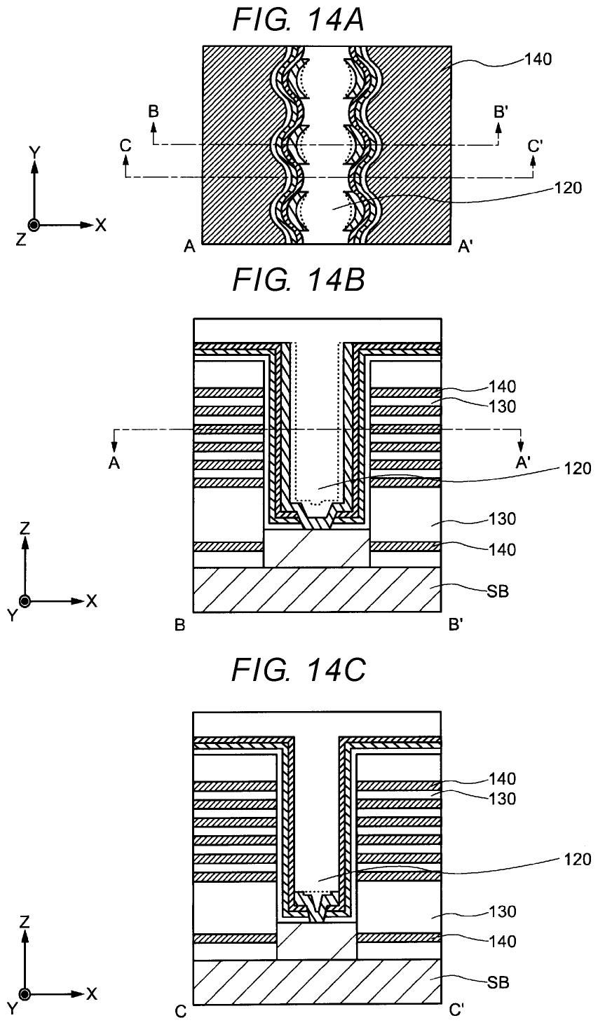

FIGS. 14A to 14C are cross-sectional view illustrating steps for further forming the insulator 120 in the method of manufacturing the semiconductor storage device according to at least one embodiment. FIG. 14A illustrates an example of a cross-sectional view taken long the line A-A′ illustrated in FIG. 14B in the XY plane. FIG. 14B illustrates an example of a cross-sectional view taken long the line B-B′ illustrated in FIG. 14A in the XZ plane. FIG. 14C illustrates an example of a cross-sectional view taken long the line C-C′ illustrated in FIG. 14A in the XZ plane.

As illustrated in FIGS. 14A to 14C, the insulator 120 is formed on substantially the entire surface of the stacked structure body. The insulator 120 is formed to be in contact with the semiconductor film 110 and the insulator 120 remaining in FIGS. 12A to 12C to be buried inside the memory trench MT. The insulator 120 is formed to cover the tunnel layer 117 of the memory cell MC on the stacked structure body. The insulator 120 may be a silicon nitride film formed, for example, by using CVD.

Though not illustrated, subsequently, the plurality of dummy films 140 are selectively removed, to form spaces between the plurality of insulating films 130. The plurality of dummy films 140 can be selectively removed, for example, by supplying an etching solution such as phosphoric acid via a slit. The space of the portion where the dummy film 140 of the lowermost layer is present exposes the side surface of the insulating layer 109. The side surface of the insulating layer 109 is thermally oxidized from this cavity to form an insulator (not illustrated). Here, the spaces of the portions where the other dummy films 140 are present expose the block layer 113 of the memory cell MC. Then, by embedding metal such as tungsten inside these spaces, the word line WL and the source-side select gate line SGS with reference to FIGS. 1A to 1C are formed, respectively. By forming the connection plug CJ to be in contact with the upper end of the semiconductor film 110 and forming the bit line BL, the semiconductor storage device 1 having the configuration illustrated in FIGS. 1A to 1C can be manufactured.

In the method of manufacturing the semiconductor storage device 1 according to at least one embodiment, by forming the width of the memory trench MT in advance to have the curvatures that periodically fluctuate, the semiconductor film 110 with the arc shape having the plurality of curvatures in the stretching direction of the memory trench MT can be easily formed.

[Modified Example of Semiconductor Storage Device]

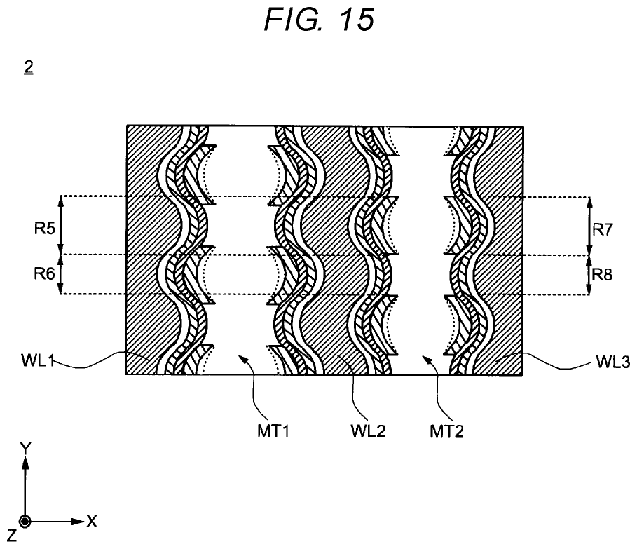

The configuration of the semiconductor storage device related to modified example is described with reference to FIG. 15. FIG. 15 is a cross-sectional view illustrating a semiconductor storage device related to a modified example.

A semiconductor storage device 2 related to the modified example is the same as the semiconductor storage device 1 except that two memory trenches MT are combined, and thus the description of common parts is omitted.

As illustrated in FIG. 15, the semiconductor storage device 2 related to the modified example the word line WL1, the word line WL2, and a word line WL3 are arranged in the same XY plane parallel to the semiconductor substrate SB via the two memory trenches MT. The word line WL1, the word line WL2, and the word line WL3 extend substantially parallel to each other in the Y direction. The word line WL1 and the word line WL2 are adjacent to each other in the X direction via a memory trench MT1. The word line WL2 is adjacent to the word line WL3 in the X direction via a memory trench MT2 opposite to the word line WL1.

In the same manner as in FIG. 1A, the word line WL1 includes the first regions R1, and the second regions R2 that protrude to the first regions R1 in the X direction. The first regions R1 and the second regions R2 are alternately arranged in the Y direction, have the curvatures from the recess portions of the first regions R1 toward the protrusions of the second regions R2, and have the curvatures from the protrusions of the second regions R2 toward the recess portions of the first regions R1. The recess portions of the first regions R1 and the protrusions of the second regions R2 that continue in the Y direction along the memory trench MT1 have curvatures that periodically fluctuate. The word line WL2 includes the third regions R3 and the fourth regions R4 that protrude to the third regions R3 in the X direction. The third regions R3 and the fourth regions R4 are alternately arranged in the Y direction, have the curvatures from the recess portions of the third regions R3 toward the protrusions of the fourth regions R4, and have the curvatures from the protrusions of the fourth regions R4 to the recess portions of the third regions R3. The recess portions of the third regions R3 and the protrusions of the fourth regions R4 that continue along the memory trench MT1 in the Y direction have the curvatures that periodically fluctuate. The first regions R1 of the word line WL1 and the third regions R3 of the word line WL2 are arranged at the same position in the Y direction and face each other via the memory trench MT1. The second regions R2 of the word line WL1 and the fourth regions R4 of the word line WL2 are arranged at the same position in the Y direction and face each other via the memory trench MT1. The width of the memory trench MT between the first regions R1 of the word line WL1 and the third regions R3 of the word line WL2 is wider than the width of the memory trench MT between the second regions R2 of the word line WL1 and the fourth regions R4 of the word line WL2 in the X direction.

As illustrated in FIG. 15, the word line WL2 further includes fifth regions R5 opposite to the fourth regions R4 and sixth regions R6 that protrude to the fifth regions R5 opposite to the third regions R3 in the X direction. The fifth regions R5 and the sixth regions R6 are alternately arranged in the Y direction. The word line WL2 has the curvatures from the recess portions of the fifth regions R5 toward the protrusions of the sixth regions R6 and has the curvatures from the protrusions of the sixth regions R6 toward the recess portions of the fifth regions R5. The recess portions of the fifth regions R5 and the protrusions of the sixth regions R6 that continue in the Y direction along the memory trench MT2 have the curvatures that periodically fluctuate. The recess portions of the fifth regions R5 and the protrusions of the sixth regions R6 that continue in the Y direction form a wavy line with gentle undulations (concavo-convex structure) in the X direction, in the Y direction. The protrusions of the fourth regions R4 and the recess portions of the fifth regions R5 of the word line WL2 are arranged at the same position in the Y direction, and the recess portions of the third regions R3 and the protrusions of the sixth regions R6 of the word line WL2 are arranged at the same position in the Y direction. That is, the concavo-convex structure in which the third regions R3 and the fourth regions R4 of the word line WL2 are formed and the concavo-convex structure in which the fifth regions R5 and the sixth regions R6 of the word line WL2 are formed are deviated by a half pitch in the Y direction. Therefore, the width of the word line WL2 in the X direction is substantially the same in the Y direction, and the memory cells can be arranged at high density.

The word line WL3 includes seventh regions R7 and eighth regions R8 that protrude to the seventh regions R7 in the X direction. The seventh regions R7 and the eighth regions R8 are alternately arranged in the Y direction. The word line WL3 has the curvature from the recess portions of the seventh regions R7 toward the protrusions of the eighth regions R8 and the curvature from the protrusions of the eighth regions R8 toward the recess portions of the seventh regions R7. The recess portions of the seventh regions R7 and the protrusions of the eighth regions R8 that continue in the Y direction along the memory trench MT2 have the curvatures that periodically fluctuate. The recess portions of the seventh regions R7 and the protrusions of the eighth regions R8 that continue in the Y direction form a wavy line with gentle undulations (concavo-convex structure) in the X direction, in the Y direction. The fifth regions R5 of the word line WL2 and the seventh regions R7 of the word line WL3 are arranged at the same position in the Y direction and face each other via the memory trench MT2. The sixth regions R6 of the word line WL2 and the eighth regions R8 of the word line WL3 are arranged at the same position in the Y direction and face each other via the memory trench MT2. Therefore, the sixth regions R6 of the word line WL2 and the eighth regions R8 of the word line WL3 are closer to each other than the fifth regions R5 of the word line WL2 and the seventh regions R7 of the word line WL3. In other words, the width of the memory trench MT2 between the fifth regions R5 of the word line WL2 and the seventh regions R7 of the word line WL3 is wider than the width of the memory trench MT2 between the sixth regions R6 of the word line WL2 and the eighth regions R8 of the word line WL3 in the X direction.

In the semiconductor storage device 2 according to the modified example, the memory trench MT1 and the memory trench MT2 that have the curvatures that periodically fluctuate are deviated by a half pitch in the Y direction, so that the constant width of the word line WL2 in the X direction can be secured, and also the memory cells can be arranged at high density.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a semiconductor substrate;
a first structure body having a plurality of first conductive films and a plurality of first insulating films alternately stacked on the semiconductor substrate in a first direction;
a first semiconductor layer extending in the first direction; and
a first memory cell disposed between the first semiconductor layer and the first structure body, wherein
the plurality of first conductive films include (i) first portions, (ii) second portions, and (iii) third portions positioned between the first portion and the second portions in a second direction, the second direction being parallel to the semiconductor substrate, the first portions, second portions, and third portions disposed at different positions in a third direction parallel to the semiconductor substrate, and having curvatures extending from the first portions to the third portions and from the second portions to the third portions, and
the first memory cell is disposed between the first semiconductor layer and the third portion.

2. The semiconductor storage device according to claim 1, wherein
the first portion and the second portion protrude toward the third portion in the third direction.

3. The semiconductor storage device according to claim 1, wherein
the first memory cell includes:
a first insulating layer disposed between the first semiconductor layer and the first conductive film;
a first charge storage layer disposed between the first insulating layer and the first conductive film; and
a second insulating layer disposed between the first charge storage layer and the first conductive film.

4. The semiconductor storage device according to claim 3, wherein
the first insulating layer, the first charge storage layer, and the second insulating layer are disposed on side surfaces of the first portions and the second portions in the third direction and extend to the first insulating layer, the first charge storage layer, and the second insulating layer disposed in the third portion.

5. The semiconductor storage device according to claim 1, further comprising:
a second structure body having a plurality of second conductive films and a plurality of second insulating films alternately stacked on the semiconductor substrate in the first direction;
a second semiconductor layer extending in the first direction; and
a second memory cell disposed between the second semiconductor layer and the second structure body, wherein
the plurality of second conductive films include fourth portions facing the first portions, fifth portions facing the second portions, and sixth portions positioned between the fourth portions and the fifth portions in the second direction, the plurality of second conductive films disposed at different positions in the third direction, facing the third portions, and having curvatures from the fourth portions to the sixth portions and from the fifth portions to the sixth portions, and
the second memory cell is disposed between the sixth portion and the second semiconductor layer.

6. The semiconductor storage device according to claim 5, wherein
the fourth portions and the fifth portions protrude to the sixth portions in the third direction.

7. The semiconductor storage device according to claim 5, wherein
the second memory cell includes:
a third insulating layer disposed between the second semiconductor layer and the second conductive film;
a second charge storage layer disposed between the third insulating layer and the second conductive film; and
a fourth insulating layer disposed between the second charge storage layer and the second conductive film.

8. The semiconductor storage device according to claim 7, wherein
the third insulating layer, the second charge storage layer, and the fourth insulating layer are disposed on side surfaces of the fourth portions and the fifth portions in the third direction, and
the third insulating layer, the second charge storage layer, and the fourth insulating layer disposed in the sixth portion are continued.

9. The semiconductor storage device according to claim 5, wherein
a distance between the third portion and the sixth portion in the third direction is greater than that between the first portion and the fourth portion in the third direction.

10. The semiconductor storage device according to claim 1, wherein the curvatures define a concavo-convex curve.

11. The semiconductor storage device according to claim 10, wherein the curvatures fluctuate in a periodic manner along the first direction.

12. The semiconductor storage device according to claim 1, wherein the first semiconductor layer is discontinuous in a region corresponding to the first portions.

13. The semiconductor storage device according to claim 12, wherein the first semiconductor layer is disposed in a recess of the second portions.

14. The semiconductor storage device according to claim 1, wherein the first memory cell has a concavo-convex surface.

15. The semiconductor storage device according to claim 3, wherein the first charge storage layer includes silicon nitride.
